(19) United States
(12) Patent Application Publication
(10) Pub. No.: US 2004/0164647 A1
(43) Pub. Date: Aug. 26, 2004

(54) Piezoelectric transducer circuit with improved shock recovery

(76) Inventor: Eric Scott Micko, Rescue, CA (US)

Correspondence Address: John L. Rogitz, Esq., ROGITZ & ASSOCIATES, Suite 3120, 750 ''B'' Street, San Diego, CA, 92101, US

(21) Appl. No.: 10/785,314

(22) Filed: Feb. 23, 2004

Related U.S. Application Data
(60) Provisional application No. 60/450,405, filed on Feb. 26, 2003.

(51) Int. Cl. H01L 41/04

(52) U.S. Cl. 310/319

(57) ABSTRACT

A resistor is placed in series between a piezoelectric transducer and its buffer/amplifier circuit to limit transient-induced current flows through the circuit.

### RELATED APPLICATIONS

Priority is claimed from U.S. provisional application serial No. 60/450,405, filed Feb. 26, 2003, incorporated herein by reference.

### I. FIELD OF THE INVENTION

The present invention relates generally to piezoelectric transducer systems.

### II. BACKGROUND OF THE INVENTION

Piezoelectric sensor systems are used in a wide variety of applications. As but one non-limiting example, some security systems detect movement in a monitored space using passive infrared (PIR) motion sensors, which detect changes in far infrared radiation (8-14 micron wavelength) due to temperature differences between an object (e.g. a human) and its background environment. Upon detection, motion sensors generally transmit an indication to a host system, which may in turn activate an intrusion “alarm”, change room lighting, open a door, or perform some other function. Such sensors advantageously are simple and relatively inexpensive.

The detectors of a PIR sensor can include pyroelectric detectors that measure changes in far infrared radiation. Such detectors operate by the “piezoelectric effect”, which causes electrical charge migration in the presence of mechanical strain. Pyroelectric detectors take the form of a capacitor—two electrically conductive plates separated by a dielectric. The dielectric can be a piezoelectric ceramic. When far infrared radiation causes a temperature change (and thus some mechanical strain) in the ceramic, electrical charge migrates from one plate to the other. If no external circuit is connected to the detector (“voltage output mode”), then a voltage that can be measured appears as the “capacitor” charges. If an external circuit is connected between the plates (“current output mode”), then a current flows.

Regardless of the particular application, a piezoelectric detector in the voltage output mode can use either a field effect transistor (FET) or an operational amplifier to couple the relatively high output impedance of the piezoelectric transducer proper (which can be hundreds of GigaOhms or higher) to a lower-impedance measurement device, as well as to amplify the small transducer signal. The output signal is developed by a load resistor. In contrast, in the current output mode, a piezoelectric transducer can be placed in a transconductance amplifier circuit, in which, in lieu of allowing the voltage between the plates of the transducer to change, charge is conducted through a feedback resistor of an amplifier to create a voltage that establishes the output signal of the circuit.

In either mode, as recognized herein the signals generated by the piezoelectric transducer usually are very small compared to the FET gate-source operating voltage and breakdown voltage as well as all of the circuit's power supply voltages. The circuits are designed to operate using these very small transducer signals. But the present invention further recognizes that when the piezoelectric detector is exposed to mechanical shock, the transducer voltage can exceed the other circuit voltages, resulting a large current flow through the detector circuit, e.g., through a forward-biased FET gate-source “diode” or through the input protection diodes of an operational amplifier. This causes the circuit to saturate, i.e., to lose the linear relationship between input signal and output signal and, hence, to generate erroneous output signals that are of little or no use until the circuit stabilizes.

In other cases, milder shocks can cause transducer-generated voltages which, while not large enough to exceed critical circuit voltages, may undergo sufficient excursion that minor FET or amplifier non-linear current flow versus voltage along the paths mentioned above can cause a noticeable voltage to remain across the transducer following the shock event.

With this in mind, the present invention is directed to reducing the recovery time of such circuits after suffering a mechanical shock.

### SUMMARY OF THE INVENTION

A piezoelectric detector includes a piezoelectric transducer, an amplifier circuit electrically connected to the piezoelectric transducer, and an element having an electrical impedance (such as an inductor or resistor, hereinafter collectively referred to as a “resistor”) in electrical series between the piezoelectric transducer and the amplifier circuit to limit transient-induced current flows through the circuit.

The non-limiting current-limiting resistor has a resistance that is less than an amplifier impedance of the amplifier circuit. The resistor preferably has a resistance that is less than a feedback resistance or load resistance of the amplifier circuit.

The piezoelectric detector can operate in a voltage output mode, and the amplifier circuit can include a FET. In this embodiment, the resistor is disposed in series between the piezoelectric transducer and the FET. Or, the piezoelectric detector can operate in a voltage output mode and the amplifier circuit can include an operational amplifier, in which case the resistor is disposed in series between the piezoelectric transducer and the operational amplifier, e.g., between the piezoelectric transducer and a non-inverting input of the operational amplifier.

Alternatively, the piezoelectric detector can operate in a current output mode, and the amplifier circuit may include an operational amplifier. In this embodiment, the resistor is disposed in series between the piezoelectric transducer and the operational amplifier, e.g., between the piezoelectric transducer and an inverting input of the operational amplifier.

In any case, the detector can be implemented in an infrared motion sensor.

In another aspect, in a detector circuit including a piezoelectric transducer and a monitoring circuit, at least one resistor is in series between the piezoelectric transducer and the monitoring circuit. The resistor has a resistance that is established to cause negligible error in a measurement signal output by the monitoring circuit during non-stress events but that limits current flow during transient stress events.

In still another aspect, a circuit includes a piezoelectric transducer and an amplifier circuit that receives, along an electrical path, a signal from the transducer and that processes the signal to produce an output. At least one resistor is in the electrical path. The circuit is configured such that the signal from the transducer must pass through the resistor prior to being received by the amplifier circuit.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a block diagram of the present system architecture;

FIG. 2 is a schematic diagram of a first embodiment showing the piezoelectric transducer in a voltage output mode using a FET;

FIG. 3 is a schematic diagram of a second embodiment showing the piezoelectric transducer in a voltage output mode using an operational amplifier; and

FIG. 4 is a schematic diagram of a third embodiment showing the piezoelectric transducer in a current output mode.

### DETAILED DESCRIPTION OF THE PREFERRED EMBODIMENT

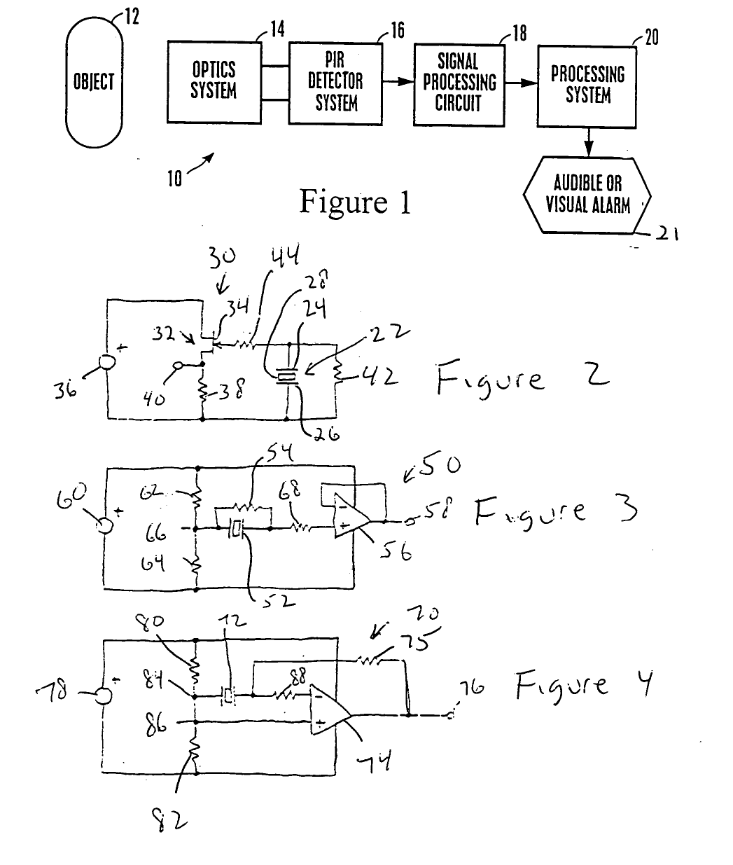

Referring initially to FIG. 1, an exemplary non-limiting system is shown, generally designated 10, for detecting a moving object 12, such as a human. The system 10 includes an optics system 14 that can include appropriate mirrors, lenses, and other components known in the art for focussing images of the object 12 onto a passive infrared (PIR) detector system 16. In response to the moving object 12, the PIR detector system 16 generates a signal that can be filtered, amplified, and digitized by a signal processing circuit 18, with a processing system 20 (such as, e.g., a computer or application specific integrated circuit) receiving the signal and determining whether to activate an audible or visual alarm 21 or other output device such as an activation system for a door, etc.

Having described one application of the piezoelectric detector of the present invention, attention is now directed to FIGS. 2-4, which show various implementations of the present inventive concept. As shown in FIG. 2, a piezoelectric transducer 22 is provided. The piezoelectric transducer 22 can be any piezoelectric transducer. In one exemplary illustration. the piezoelectric transducer 22 is a pyroelectric detector that measures changes in far infrared radiation by the “piezoelectric effect”, which causes electrical charge migration in the presence of mechanical strain that can be induced by, e.g., far infrared radiation-induced temperature change. The piezoelectric transducer 22 may take the form of a capacitor, i.e., two electrically conductive plates 24, 26 separated by a dielectric 28 which can be a piezoelectric ceramic. When the ceramic 28 of the piezoelectric transducer 22 experiences mechanical strain, electrical charge migrates from one plate 24, 26 to the other plate 26, 24.

As shown in FIG. 2, in one embodiment the piezoelectric transducer 22 can be part of a voltage output mode piezoelectric detector, generally designated 30, that includes a buffer/amplifier circuit, generally designated 32. The circuit 32 can be thought of as a monitoring circuit for the piezoelectric transducer 22. The circuit 32 impedance-buffers and amplifies the signal from the transducer 22.

In the circuit 32 shown in FIG. 2, a FET 34 is provided that receives the output of the piezoelectric transducer 22 combined with a load resistor 42, which is in electrical parallel with the piezoelectric transducer 22 as shown. A power supply 36, such as a five volt dc power supply, can be placed in electrical parallel with the FET 34, which is in electrical series with a FET source follower resistor 38. The output voltage signal of the circuit 32, which can be sensed at an output signal tap 40 at the source of the FET 34, is developed across the FET source follower resistor 38.

In accordance with the present invention, a transient current limiting resistor 44 is placed in series between the piezoelectric transducer 22 and the buffer/amplifier circuit 32. It is to be understood that by “transient current limiting resistor” the present invention intends the ordinary and customary usage of “resistor”, which includes components commonly referred to as “resistors” and inductors and which consequently does not include a conductor such as a wire or lead that extends between two components and that has some negligible resistance.

In the specific embodiment shown in FIG. 2, the transient current limiting resistor 44 is placed in series between the piezoelectric transducer 22 and the gate of the FET 34. The resistance of the transient current limiting resistor 44 is established such that it is relatively small compared to the impedance of the FET 34 and also compared to the resistance of the load resistor 42 of the FET 34, so that during normal operation its effect on the current flowing within the detector 30 is negligible.

FIG. 3 shows a voltage output mode detector 50 that includes a piezoelectric transducer 52 in parallel with a load resistor 54 across which the output signal of the circuit is developed. The output of the piezoelectric transducer 52 is sent to the non-inverting input of an operational amplifier 56, with the output signal of the operational amplifier 56 being sensed at an output terminal 58 of the amplifier 56. A power supply 60 supplies power for the circuit, and it is in parallel with two series resistors 62, 64 between which is a voltage reference tap 66 for the piezoelectric transducer 52.

In accordance with the present invention, a transient current limiting resistor 68 is placed in series between the piezoelectric transducer 52 and the operational amplifier 56. In the specific embodiment shown in FIG. 3, the transient current limiting resistor 68 is placed in series between the piezoelectric transducer 52 and the non-inverting input of the operational amplifier 56. The resistance of the transient current limiting resistor 68 is established such that it is relatively small compared to the impedance of the operational amplifier 56 and is also small compared to the resistance of the load resistor 54, so that during normal operation its effect on the current flowing within the detector 50 is negligible.

FIG. 4 shows a current output mode detector 70 that includes a piezoelectric transducer 72 in a transconductance circuit. The output of the piezoelectric transducer 72 is sent to the inverting input of an operational amplifier 74, with the output signal of the detector 70 being developed across a feedback resistor 75 and sensed at an output terminal 76 of the operational amplifier 74. A power supply 78 supplies power for the circuit, and it is in parallel with two series resistors 80, 82 between which is a voltage reference tap 84 for the piezoelectric transducer 72. Also, a tap 86 is between the resistors 80, 82 and is connected to the non-inverting input of the operational amplifier 74. Instead of an operational amplifier the circuit shown in FIG. 4 could use a common-source FET amplifier circuit for its gain element.

In accordance with the present invention, a transient current limiting resistor 88 is placed in series between the piezoelectric transducer 72 and the operational amplifier 74. In the specific embodiment shown in FIG. 4, the transient current limiting resistor 88 is placed in series between the piezoelectric transducer 72 and the inverting input of the operational amplifier 74. The resistance of the transient current limiting resistor 88 is established such that it is relatively small compared to the impedance of the operational amplifier 74 and the resistance of the feedback resistor 75, so that during normal operation its effect on the current flowing within the detector 70 is negligible.

While the particular PIEZOELECTRIC TRANSDUCER CIRCUIT WITH IMPROVED SHOCK RECOVERY as herein shown and described in detail is fully capable of attaining the above-described objects of the invention, it is to be understood that it is the presently preferred embodiment of the present invention and is thus representative of the subject matter which is broadly contemplated by the present invention, that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more”. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. §112, sixth paragraph, unless the element is expressly recited using the phrase “means for” or, in the case of a method claim, the element is recited as a “step” instead of an “act”. Absent express definitions herein, claim terms are to be given all ordinary and accustomed meanings that are not irreconciliable with the present specification and file history.

What is claimed is:

1. A piezoelectric detector, comprising:
a piezoelectric transducer;
an amplifier circuit electrically connected to the piezoelectric transducer; and
a resistor in electrical series between the piezoelectric transducer and the amplifier circuit to limit transient-induced current flows through the circuit.

2. The detector of claim 1, wherein the resistor has a resistance that is less than an amplifier impedance of the amplifier circuit.

3. The detector of claim 1, wherein the resistor has a resistance that is less than at least one of: a feedback resistance, and a load resistance, of the amplifier circuit.

4. The detector of claim 1, wherein the piezoelectric detector operates in a voltage output mode, and the amplifier circuit includes a FET, the resistor being disposed in series between the piezoelectric transducer and the FET.

5. The detector of claim 1, wherein the piezoelectric detector operates in a voltage output mode, and the amplifier circuit includes an operational amplifier, the resistor being disposed in series between the piezoelectric transducer and the operational amplifier.

6. The detector of claim 5, wherein the resistor is in series between the piezoelectric transducer and a non-inverting input of the operational amplifier.

7. The detector of claim 1, wherein the piezoelectric detector operates in a current output mode, and the amplifier circuit includes an operational amplifier, the resistor being disposed in series between the piezoelectric transducer and the operational amplifier.

8. The detector of claim 7, wherein the resistor is in series between the piezoelectric transducer and an inverting input of the operational amplifier.

9. The detector of claim 1, wherein the detector is implemented in an infrared motion sensor.

10. In a detector circuit including a piezoelectric transducer and a monitoring circuit, at least one resistor in series between the piezoelectric transducer and the monitoring circuit, the resistor having a resistance established to cause negligible error in a measurement signal output by the monitoring circuit at least during non-stress events but limiting current flow during transient stress events.

11. The circuit of claim 10, wherein the resistor has a resistance that is less than an amplifier impedance of the monitoring circuit.

12. The circuit of claim 10, wherein the resistor has a resistance that is less than at least one of: a feedback resistance, and a load resistance, of the monitoring circuit.

13. The circuit of claim 10, wherein the piezoelectric detector operates in a voltage output mode, and the monitoring circuit includes a FET, the resistor being disposed in series between the piezoelectric transducer and the FET.

14. The circuit of claim 10, wherein the piezoelectric detector operates in a voltage output mode, and the monitoring circuit includes an operational amplifier, the resistor being disposed in series between the piezoelectric transducer and the operational amplifier.

15. The circuit of claim 14, wherein the resistor is in series between the piezoelectric transducer and a non-inverting input of the operational amplifier.

16. The circuit of claim 10, wherein the piezoelectric detector operates in a current output mode, and the monitoring circuit includes an operational amplifier, the resistor being disposed in series between the piezoelectric transducer and the operational amplifier.

17. The circuit of claim 16, wherein the resistor is in series between the piezoelectric transducer and an inverting input of the operational amplifier.

18. The circuit of claim 10, wherein the circuit is implemented in an infrared motion sensor.

19. A circuit, comprising:
at least one piezoelectric transducer;
at least one amplifier circuit receiving, along an electrical path, a signal from the transducer and processing the signal to produce an output; and
at least one resistor in the electrical path, the circuit being configured such that the signal from the transducer must pass through the resistor prior to being received by the amplifier circuit.

20. The circuit of claim 19, wherein the resistor has a resistance that is less than an amplifier impedance of the amplifier circuit.

21. The circuit of claim 19, wherein the resistor has a resistance that is less than at least one of: a feedback resistance, and a load resistance, of the amplifier circuit.

22. The circuit of claim 19, wherein the piezoelectric detector operates in a voltage output mode, and the amplifier circuit includes a FET, the resistor being disposed in series between the piezoelectric transducer and the FET.

23. The circuit of claim 19, wherein the piezoelectric detector operates in a voltage output mode, and the amplifier circuit includes an operational amplifier, the resistor being disposed in series between the piezoelectric transducer and the operational amplifier.

24. The circuit of claim 23, wherein the resistor is in series between the piezoelectric transducer and a non-inverting input of the operational amplifier.

25. The circuit of claim 19, wherein the piezoelectric detector operates in a current output mode, and the amplifier circuit includes an operational amplifier, the resistor being disposed in series between the piezoelectric transducer and the operational amplifier.

26. The circuit of claim 25, wherein the resistor is in series between the piezoelectric transducer and an inverting input of the operational amplifier.

27. The circuit of claim 19, wherein the circuit is implemented in an infrared motion sensor.
